(19) United States
(12) Patent Application Publication
(10) Pub. No.: US 2018/0218670 A1
(43) Pub. Date: Aug. 2, 2018

(54) APPARATUS AND METHOD FOR DISTRIBUTED CONTROL OF A SEMICONDUCTOR DEVICE ARRAY

(71) Applicant: Rohinni, LLC, Coeur d'Alene, ID (US)

(72) Inventors: Andrew Huska, Liberty Lake, WA (US); Justin Wendt, Post Falls, ID (US)

(21) Appl. No.: 15/881,627

(22) Filed: Jan. 26, 2018

Related U.S. Application Data
(60) Provisional application No. 62/451,630, filed on Jan. 27, 2017.

(51) Int. Cl. G09G 3/325; H01L 25/075; H01L 33/62; H01L 25/16; H01L 33/00; H01L 21/683

(52) U.S. Cl. CPC G09G 3/325; H01L 25/0753; H01L 33/62; H01L 25/167; H01L 33/0079; G09G 2370/08; H01L 2933/0066; H01L 2221/68363; G09G 2320/0666; G09G 2320/0653; H01L 21/6835

(57) ABSTRACT

A semiconductor device array includes a plurality of first semiconductor devices arranged in an array and a plurality of second semiconductor devices distributed throughout the array of the plurality of first semiconductor devices. Each of the second semiconductor devices is interconnected with at least one of the first semiconductor devices. The second semiconductor devices are configured to function as a controller over a function of the at least one of the first semiconductor devices, respectively.

### CROSS REFERENCE TO RELATED PATENT APPLICATIONS

This application claims priority to and incorporates U.S. Provisional Patent Application 62/451,630, filed Jan. 27, 2017, entitled “Apparatus and Method for Distributed Control of a Semiconductor Device Array,” in its entirety by reference. This application also incorporates U.S. patent application Ser. No. 14/939,896, now patented as U.S. Pat. No. 9,633,883, filed on Nov. 12, 2015, entitled “Apparatus for Transfer of Semiconductor Devices,” in its entirety by reference.

### BACKGROUND

Generally, modern displays may be illuminated via OLED or LED. In the case of an OLED illuminated display, the OLED is controlled via an OLED driver chip (also called simply “OLED driver” or a “controller”). An OLED driver is a current-controlling integrated circuit (“IC”) that controls and drives electrical current through (or sinks current from) OLED pixels. The amount of current driven via an OLED driver usually ranges from a few hundred microamps per pixel to a couple milliamps per pixel. Typically, OLED drivers are designed to address and control anywhere from a few thousand to many thousands of pixels because most graphical displays have many pixels. For example, even a small 96×128 pixel display has over 10,000 individual areas to control, while many basic, though larger displays may easily have between 250 k to 2 M+ pixels. Regardless, OLED drivers are very small because of the markets for which they are designed. In some instances, the lateral dimensions of an OLED driver may be as small as 2 mm by 10-15 mm, and a height dimension may be less than 1 mm thick. Despite the small size, an OLED driver may have hundreds of pins on the bottom side thereof via which the connected pixels are controlled.

Additionally, OLED drivers usually have standard interfaces via which the OLED drivers can be controlled using standard computer devices. The interfaces enable calibration of the drivers' output (e.g., adjustments to brightness uniformity or color balance, etc. and synchronization of multiple drivers in a single system. Furthermore, OLED drivers are relatively inexpensive, currently costing about $1.00 each.

An LED driver chip is used to drive an LED illuminated display, and is somewhat similar to an OLED driver. Compared to the size of OLED drivers, LED drivers are typically relatively large and are further designed to deliver a large amount of current to LEDs (e.g., ranging from 10 mA to many hundreds of mA). Inasmuch as the amount of current applied to an LED affects the brightness of the LED, in a typical LED array where there are relatively few LEDs, the LEDs used need to be very bright. Even if the selected LED driver can be dimmed to be very low current, the LED driver is still often relatively large due to the design capability of going from very low to very high. For example, an LED driver that can control 48 pixels or even 1200 in a matrix, might be 7 mm×7 mm×2 mm. An LED driver as described here, can currently cost about $5.00 each. The LED driver size and cost has not been greatly influenced by low cost high volume markets like OLED display controllers.

### SUMMARY

A micro-sized semiconductor die, such as unpackaged (e.g., bare die) micro-sized LEDs that are contemplated for use in display backlighting apparatuses are extremely small and thin compared to more commonly used LEDs, which are easier to implement in a display. For example, the thickness of an unpackaged micro-sized LED die (e.g., height that a die extends above a surface) may range from about 12 microns to about 400 microns, and a lateral dimension of a micro-sized LED die may range from about 20 microns to about 800 microns. Furthermore, micro-sized LED die are currently substantially less expensive than the larger more commonly used LEDs.

Despite the size difference, micro-sized LEDs can handle the range of current of the larger, more commonly used LEDs (e.g., (10-20 mA). However, in view of the size and cost savings associated with micro-sized LEDs, it is possible to implement between a few hundred to a few thousands or more in a display or illumination circuit that would normally use a significantly smaller number of the larger LEDs. In such a situation using a greater quantity of micro-sized LEDs, the individual LEDs do not need to be extremely bright because collectively the group is very bright. Further, by minimizing the brightness, the micro-sized LEDs last longer and are more energy efficient than the larger counterparts. For example, the micro-sized LEDs may be energized using current ranging from a μA level to low single digit mA level. Such low current levels match well with the capabilities of an OLED driver. Thus, in an example embodiment, using an OLED driver to drive micro-sized LEDs, the features, economies of scale, and size associated with the OLED driver are complementary to the micro-sized LEDs, thereby enabling a superior level of LED lighting control resolution is that is unseen conventionally. Nevertheless, in another embodiment, the use of an LED driver may also provide similar results. Indeed, a smaller LED driver may be made and may be well-suited for driving low current to a large or small number of LEDs in parallel or in a matrix.

In view of the above information and advantages discovered, a unique control scheme of distributed control of an LED array is described herein below.

### BRIEF DESCRIPTION OF THE DRAWINGS

The Detailed Description is set forth with reference to the accompanying figures. In the figures, the left-most digit(s) of a reference number identifies the figure in which the reference number first appears. The use of the same reference numbers in different figures indicates similar or identical items. Furthermore, the drawings may be considered as providing an approximate depiction of the relative sizes of the individual components within individual figures. However, the drawings are not to scale, and the relative sizes of the individual components, both within individual figures and between the different figures, may vary from what is depicted. In particular, some of the figures may depict components as a certain size or shape, while other figures may depict the same components on a larger scale or differently shaped for the sake of clarity.

FIG. 1 illustrates a schematic of a driver chip according to an embodiment of the instant application.

FIG. 2 illustrates a scaled representation of a driver chip according to an embodiment of the instant application.

FIG. 3 illustrates a schematic of a controller chip connected to multiple LEDs according to an embodiment of the instant application.

FIG. 4 illustrates a microscope image of a 12-channel LED driver sitting next to LEDs that are spaced, for example, at 2 mm pitch, according to an embodiment of the instant application.

### DETAILED DESCRIPTION

### Overview

This disclosure is directed to a method and apparatus of a distributed control scheme for controlling an LED array. The LEDs of the array may be of any size, including but not limited to micro-sized LEDs, and may be controlled in groupings of as small as 1 LED, or 2 LEDs, or 3 LEDs, or 4 LEDs, or more. That is, in an array of LEDs, for example used to illuminate a display device, a plurality of OLED or LED drivers (“controllers”) may be distributed throughout the array, disposed among the LEDs and connected thereto, to drive the LEDs in groups of one or more LEDs per driver. The implementation of the aforementioned drivers as used in a device, such as a display device, according to the instant application, may provide a smaller, cheaper, faster, and more versatile system for controlling an LED array.

### Illustrative Embodiment of a Controller Chip

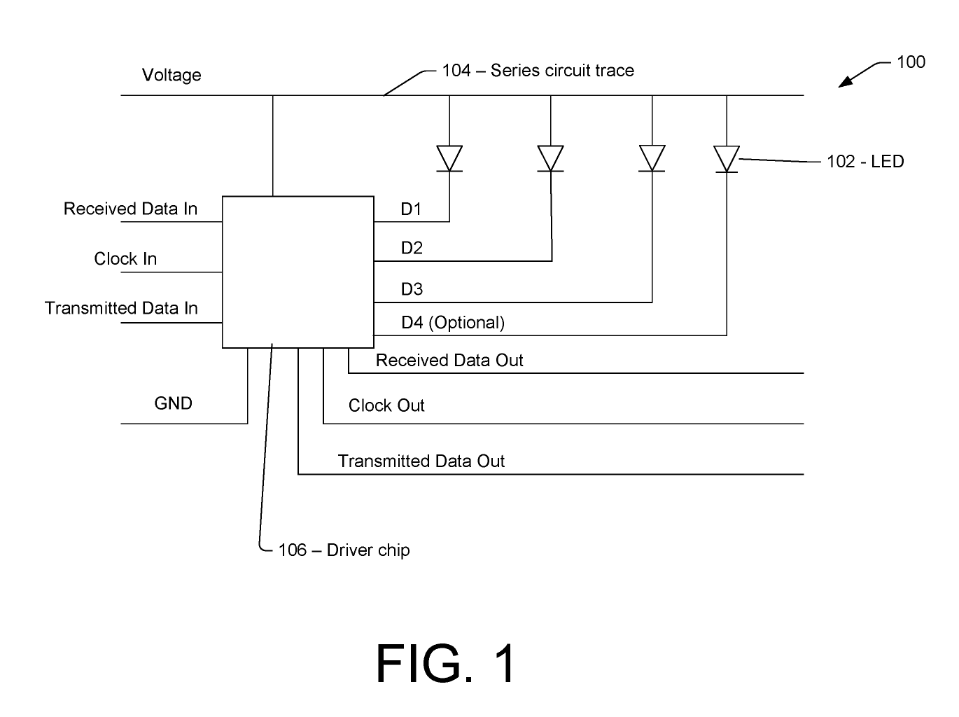

In an embodiment, FIG. 1 depicts a schematic 100 for control of one or more LEDs 102 interconnected in a series circuit trace 104 and controlled by a controller chip 106. The controller chip 106 is contemplated for use as an LED driver in a distributed control of an array of LEDs 102 according to the instant application, may have one or more of the following properties:
May be used as a bare die mounted like a “flip chip” using a direct transfer system, such as one or more of the embodiments of machines and/or methods of directly transferring die, which are disclosed in the aforementioned U.S. Pat. No. 9,633,883
   Chip may be passivated to prevent shorts from the circuit substrate to electrical components of the chip that are between contact pads
   Specific contact pad placement to facilitate a repeating, continuous circuit layout
   May be directly mounted to the circuit substrate with solder, Anisotropic Conductive Film (“ACF,” or Z-axis adhesive), or similar materials
May be such that no external components are required to define the chip's behavior
   In an embodiment, no required passive components to set current limit, define chip address, or stabilize the power
May have an output buffer design that allows one frame of data to be displayed while the next frame is being clocked (transferred) in to the chip
   A signal may be encoded into one or more of the communication lines to cause a switch to the next buffer (in protocol details)
May control approximately 3 to 16 LEDs 102 with 6 to 16 bit dimming resolution (although these are not limitations)
   For RGB, RGBW, or W (for illumination or backlighting) control
   One or more channels could support defining of a calibration offset from the factory that will scale the input data during operation so the host does not need to worry about calibrating brightness across a large array
   High depth resolution allows some extra bits for calibration and offset of max output
   One or more channels may be individually current controlled with a maximum current according to the peak efficiency of the LEDs under control (e.g., approximately 1-4 mA for a micro-sized LED)
   One or more channels may be current limited on each pulse to operate near the LEDs peak efficiency point throughout their dimming range
May be tolerant of 12V operation to endure large runs which result in large voltage drop toward the far end
Communications rate may be sufficient to communicate with thousands of controllers while maintaining high frame rates
   Up to 240 Hz refresh rate
   Up to 48 bits per controller
   4096 controllers in a single network (may be sufficient for a 100″ TV backlight with 10 mm LED spacing)
   50 Mbps serial communication
   Chip addressing can be implied by position on the network, where a chip removes a certain number of data bits from the received frame data then forwards it to the next chip on the network. Doing this may help: maintain the number of devices driven by each output pin low; eliminate addressing bits from the data bus; and eliminate address decoding logic from the chip design. The entire network is serially connected.
Communications protocol
   Start of frame (buffer swap)
   Calibration save mode (optional)
   1-wire, 2-wire, and 3-wire designs, however one skilled in the art may realize that there may be other protocols that may achieve similar results
May have a 7 to 12 or more pin chip design (see inset Image 1; and FIG. 1, for example)
   Power (12V)
   LED cathode 1
   LED cathode 2
   LED cathode 3
   LED cathode n or x-y (optional)
   GND
   Received data in (frame data from host or previous chip)
   Received data out (buffered output to next chip)
   Clock in (optional)
   Clock out (optional)
   Transmitted data out (diagnostic/status data to host or next chip) (optional)
   Transmitted data in (diagnostic/status data from previous chip) (optional)
   Total die size may be approximately 0.75 mm×0.75 mm to enable 1 mm pitch LED LightString designs
   Contact pad size may be approximately 75 to 100 μm square, contact pad spacing may be approximately 75 to 100 μm
   Pins may be strategically laid out to support continuous circuit replication on a single layer circuit substrate (no signals crossing over others to go from one chip to the next)

In an embodiment, LED control chips, such as those described above, may be distributed throughout the LED array itself, and may all be connected to the same power and data lines. An LED array having controllers distributed as such may provide greater ability to scale the LED array to custom fit a wide range of display sizes.

In an embodiment, an LED array with controllers may be formed as a “lightstring.” A lightstring may be a circuit strip of controlled LEDs (hence, lightstring) that can be cut to a desired length and laid in numerous rows to create any sized TV backlight. The circuit strip may therefore include OLED controllers or LED controllers distributed along a length of the strip interspersed by one or more groups of LEDs. As such, the control of the LEDs may scale simply with the predetermined size of the backlight. Furthermore, the lightstring circuit may have a couple power traces and a few data signals that run the length thereof with the controllers being individually connected to a unique segment of LEDs along the strip. A lightstring may be manufactured using a machine and/or method as disclosed in U.S. Pat. No. 9,633,883.

In an embodiment of a display device implementing a lightstring, a plurality of rows or columns of the lightstring LED strips may be laid down behind a display panel, which significantly simplifies manufacturing. That is, a series of lightstrings laid consecutively with or without spacing therebetween, where each lightstring is cut to the appropriate length for the particular display device minimizes the need for expensive tooling for conventional giant circuits.

As indicated above, a display device implementing an array of LEDs with controllers disposed among the LEDs provides distributed control of the LEDs, so the control circuits scale evenly with the LEDs making the design modular for various display sizes.

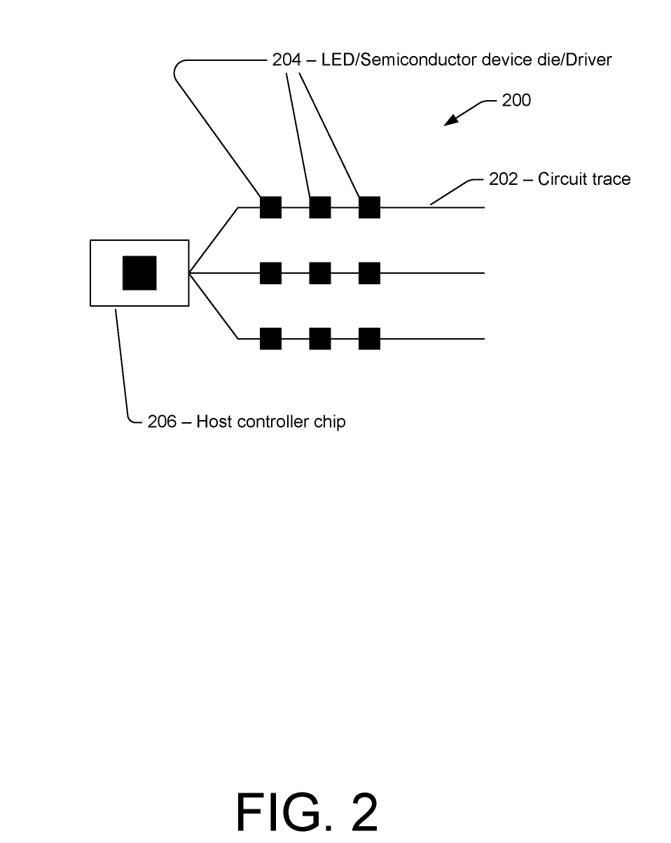

In FIG. 2, for an example embodiment, a schematic 200 is illustrated depicting multiple rows of circuit trace 202 serially connecting two or more semiconductor device die 202, such as LEDs and/or drivers, all controlled by a host controller chip 206.

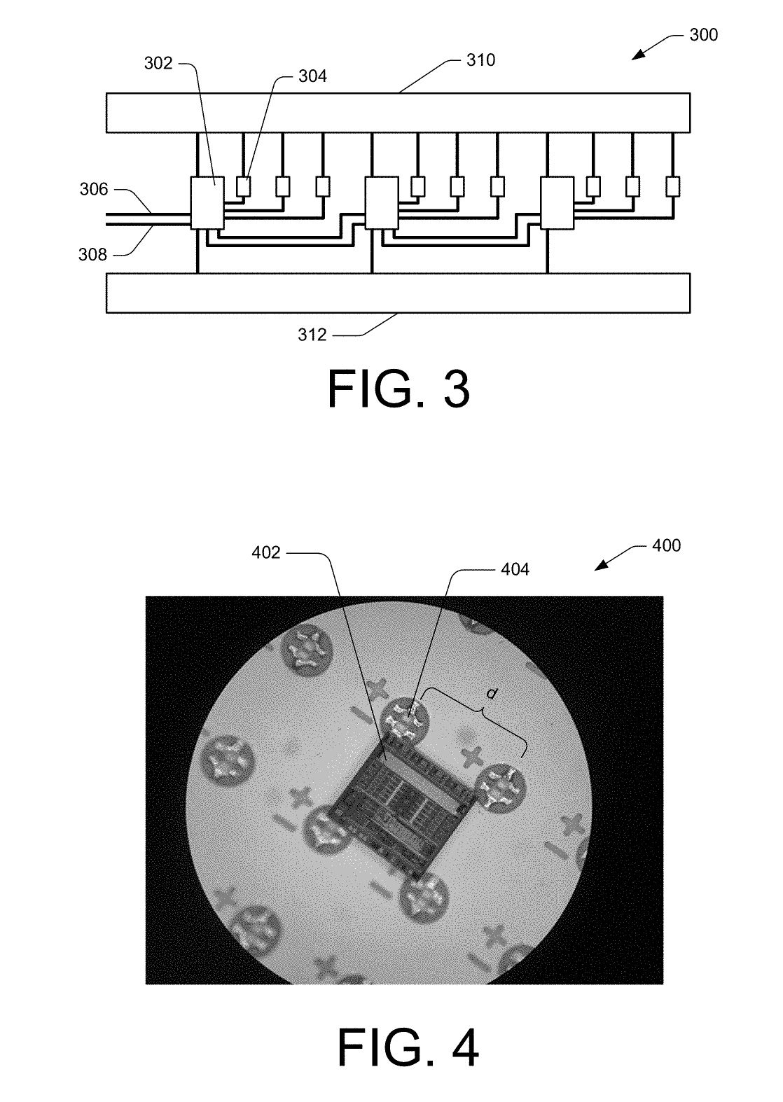

In FIG. 3, for an example embodiment, a schematic 300 shows a plurality of serially connected driver chips 302, each driving three (as depicted, but not limited to three) LEDs 304. Additionally depicted are the circuit trace lines for data transmission 306 and a clock in line 308. The bar depicted above the circuitry represents a power connection 310, and the bar depicted below the circuitry represents the ground connection 312. As depicted, such a circuit may be representative of a lightstring.

FIG. 4, for an example embodiment, depicts an image 400 of a 12-channel LED driver 402 disposed adjacent to LEDs 404 spaced at a predetermined pitch d, for example, at 2 mm pitch. The driver 402 may be for high current, around 50 mA. However, the individual micro-sized LEDs 404 contemplated for use generally use 1 to 5 mA. Therefore, the driver 402 can be much smaller than that depicted. Driver 402 may be further customized for direct transfer placement, for example by moving all signal contacts to the edge and increasing the contact pad size, simultaneously shrinking the process size so the entire driver 402 may be about 700 microns×700 microns, or smaller. The driver 402 shown in FIG. 4 is about 1.6 mm×1.6 mm.

Moreover, the lightstrings may be strips of different pitch (distance between LEDs) may be made for different qualities of TVs. As non-limiting examples, an embodiment of a display device may include strips with LEDs every 40 mm, and the strips may be spaced apart by 40 mm center-to-center, or strips may have a 10 mm LED pitch four times as many strips (compared to spacing at 40 mm apart) to produce an even higher quality backlight that is also thinner than the 40 mm example, because thickness of the light diffuser of the display is ¼ of the 40 mm, since the LED spacing is ¼ the distance of the 40 mm version.

Furthermore, in an embodiment of a display device using an array of LEDs where the individual LEDs can have their brightness controlled, the dynamic range of LCD displays (back or edge lit by LEDs) may increase to an extent to rival the dynamic range capabilities of an OLED TV, for example. For instance, such a display may have blacker blacks and much brighter whites, which an OLED display is incapable of producing. Generally, the smaller the pitch between LEDs, the more accurate the local dimming capabilities may be. One reason that dynamic range is sometimes an issue with LCDs is that the LCD shutters are unable to block the light completely enough, which leads to some light leakage or glow. Whereas with an OLED display, the OLED provides mini light sources, which when turned off, become completely black. Thus, by distributing the control of an LED array so an individual backlight may be turned off, there is no light to pass through a shutter to leak.

A display device, such as a TV or computer or phone screen may integrate the backlight control with the image data and timing controller of the display such that the backlight works in harmony with the display to do complex localized dimming and provide efficiency improvements. Thus, a display manufacturer need not redesign a large and/or expensive PCB and circuit to simply add a few more channels. To the contrary, an LED array having controllers distributed as disclosed herein allows one to easily add more and/or longer strips of lightstring in the backlight housing. The host controller functionality may therefore be much simpler and may send out data to more LED drivers on the same data bus based on a software definition of the driver arrangement.

### CONCLUSION

Although several embodiments have been described in language specific to structural features and/or methodological acts, it is to be understood that the claims are not necessarily limited to the specific features or acts described. Rather, the specific features and acts are disclosed as illustrative forms of implementing the claimed subject matter.

What is claimed is:

1. A semiconductor device array, comprising:
a plurality of first semiconductor devices arranged in an array; and
a plurality of second semiconductor devices distributed throughout the array of the plurality of first semiconductor devices, each of the second semiconductor devices being interconnected with at least one of the first semiconductor devices, and the second semiconductor devices being configured to function as a controller over a function of the at least one of the first semiconductor devices, respectively.

2. The semiconductor device array of claim 1, wherein the plurality of first semiconductor devices are LEDs.

3. The semiconductor device array of claim 2, wherein the LEDs are micro-sized LEDs.

4. The semiconductor device array of claim 1, wherein the plurality of second semiconductor devices are controllers.

5. The semiconductor device array of claim 4, wherein the controllers are OLED controllers.

6. The semiconductor device array of claim 5, wherein the plurality of first semiconductor devices are micro-sized LEDs.

7. The semiconductor device array of claim 1, wherein the plurality of second semiconductor devices are controller chips that include one or more of the following properties:
Used as a bare die mounted like a “flip chip” using a direct transfer system
Passivated to prevent shorts from a circuit substrate to electrical components of the controller that are between contact pads
Specific contact pad placement to facilitate a repeating, continuous circuit layout
Directly mounted to the circuit substrate with solder, Anisotropic Conductive Film (“ACF,” or Z-axis adhesive), or similar materials
No external components are required to define the controller's behavior
No required passive components to set current limit, define controller address, or stabilize power
Output buffer design that allows one frame of data to be displayed while a next frame is being clocked (transferred) in to the controller
A signal may be encoded into one or more communication lines to cause a switch to a subsequent buffer
Controls approximately 3 to 16 LEDs with 6 to 16 bit dimming resolution
For RGB, RGBW, or W (for illumination or backlighting) control
One or more channels support defining of an original calibration offset that may scale input data during operation so a host does not calibrate brightness across the semiconductor device array
High depth resolution that allows extra bits for calibration and offset of max output
One or more channels that are individually current controlled with a maximum current according to peak efficiency of the LEDs under control
One or more channels that are current limited on each pulse to operate near the LEDs peak efficiency point throughout respective dimming ranges
Tolerant of 12V operation to endure large runs which result in large voltage drop toward a far end
Communications rate is sufficient to communicate with thousands of controllers while maintaining high frame rates
Up to 240 Hz refresh rate
Up to 48 bits per controller
4096 controllers in a single network
50 Mbps serial communication
Controller addressing is implied by position in the semiconductor device array, where a controller removes a certain number of data bits from a received frame data then forwards it to a next controller in the semiconductor device array
Communications protocol
Start of frame (buffer swap)
Calibration save mode (optional)
1-wire, 2-wire, and 3-wire designs
7 to 12 pin controller design
Power (12V)
LED cathode 1
LED cathode 2
LED cathode 3
optional LED cathode n
GND
Received data in (frame data from host or previous controller)
Received data out (buffered output to next controller)
Clock in (optional)
Clock out (optional)
Transmitted data out (diagnostic/status data to host or next controller)
Transmitted data in (diagnostic/status data from previous controller)
Sized approximately 0.75 mm×0.75 mm
Contact pad size approximately 75 to 100 μm square, contact pad spacing approximately 75 to 100 μm
Pins may be strategically laid out to support continuous circuit replication on a single layer circuit substrate, where no signals cross over others to go from a first controller to a subsequent controller.

8. The semiconductor device array of claim 1, wherein the plurality of first semiconductor devices and the plurality of second semiconductor devices are disposed in series.

9. A method of forming a semiconductor device array, the array including:
a plurality of first semiconductor devices arranged in an array, and a plurality of second semiconductor devices distributed throughout the array of the plurality of first semiconductor devices, each of the second semiconductor devices being interconnected with at least one of the first semiconductor devices, and the second semiconductor devices being configured to function as a controller over a function of the at least one of the first semiconductor devices, respectively,
the method comprising:
transferring the plurality of first semiconductor devices to a circuit; and
transferring the plurality of second semiconductor devices to the circuit.

10. The method of claim 9, wherein at least one of the transferring the plurality of first semiconductor devices or the transferring the plurality of second semiconductor devices is performed as a direct transfer process from a substrate to the circuit.

11. The method of claim 9, wherein the transferring the plurality of second semiconductor devices includes attaching the plurality of second semiconductor devices in between adjacent a pair of placement positions of first semiconductor devices.

12. The method of claim 9, wherein the plurality of first semiconductor devices and the plurality of second semiconductor devices are transferred to a circuit so as to be connected in series.

13. The method of claim 9, wherein the circuit is scalable in size by continuously extending an interconnected series of the first semiconductor devices and the second semiconductor devices in a linear direction.

14. A display device comprising:
a distributed control circuit of an array of LEDs.

15. The display device of claim 14, wherein the display device is one of a television, a phone, a tablet, a computer screen, or an electronic display.

16. The display device of claim 14, wherein the distributed control circuit includes:
the array of LEDs; and
a series of interconnected LED driver chips.

17. The display device of claim 16, wherein each LED driver chip is configured to control a range of 1 to 12 LEDs.

18. The display device of claim 14, wherein the array of LEDs is formed of consecutive rows of circuit strings having LEDs connected in series.

19. The display device of claim 14, wherein control of the array of LEDs is distributed among a plurality of driver chips that are interspersed among the LEDs, such that display data is passed from driver chip to driver chip, each driver chip using a portion of the display data to control illumination of one or more LEDs.

20. The display device of claim 14, wherein the LEDs are micro-sized LEDs.
